(19) United States
(12) Patent Application Publication
(10) Pub. No.: US 2017/0074692 A1
(43) Pub. Date: Mar. 16, 2017

(54) DEVICE COMPRISING A SENSOR PROTECTED BY RESIN

(71) Applicant: SC2N, Creteil (FR)

(72) Inventors: Mathieu Gronier, Saint-Germain-Le-Vasson (FR); Olivier Gueguen, Caen (FR); Denis Gravat, Creteil (FR)

(73) Assignee: SC2N, Creteil (FR)

(21) Appl. No.: 15/104,066

(22) PCT Filed: Dec. 11, 2014
(86) PCT No.: PCT/FR2014/053274

§ 371 Date: Nov. 23, 2016

(30) Foreign Application Priority Data
Dec. 12, 2013 (FR) 1362524

(51) Int. Cl. G01D 11/24; B29C 39/10; G01L 19/14; H05K 1/18; G01L 19/06

(52) U.S. Cl. CPC G01D 11/245; H05K 1/18; G01L 19/0672; G01L 19/147; B29C 39/10; H05K 2201/10151; B29L 2031/3425

(57) ABSTRACT

The present invention concerns a device comprising:—a casing (10) comprising a side wall and a bottom (18) so as to define a cavity (12);—a resin (14) filling the cavity in such a way as to submerge the electronic component, leaving said sensitive element protruding.—an electronic component (32) comprising a sensor (34) provided with a sensitive element (36);—the electronic component resting on at least one pad (30) protruding from said side wall or from said bottom, so as to prevent air bubbles from forming in the resin, the pad being separated from the side wall (16) by a distance d greater than 1 mm or in contact with the side wall (16).

The invention relates to a device comprising a housing in which a sensor, partially embedded in resin, is located.

In automotive applications, certain electronic components must be protected in order to increase their service life. For this purpose, it is known to place them in housings, and then fill the housing with a liquid resin which hardens to protect them from the external environment.

When an electronic component includes a sensor whose sensing element must be exposed to its environment, the resin must not, however, cover this sensing element.

Probably under the effect of changes in temperature or pressure, cracks may appear in the resin, potentially contacting the electronic component with the outside environment. Welds or tracks of the electronic component may then oxidize, which reduces its service life.

There is a need for an improved device conferring protection to the electronic component.

An objective of the present invention is to, at least partially, meet this need.

The invention proposes a device comprising:
a housing having a side wall and a bottom so as to define a cavity;
an electronic component comprising a sensor provided with a sensing element;
a resin filling the cavity so as to submerge the electronic component while letting emerge said sensing element; the electronic component resting on at least one pad projecting from said side wall or said bottom so as to prevent air bubble formation in the resin.

According to the invention, said at least one pad is spaced from the side wall by a distance greater than 1 mm, or is in contact with said side wall.

As discussed in more detail in the following description, such an arrangement improves the service life of the electronic component. Without being bound by a theory, the inventors consider that the arrangement claimed limits the bubble formation in the vicinity of the at least one pad, these bubbles being considered as the source of some cracks.

A device according to the invention may further comprise one or more of the following optional features:
the sensor is a pressure sensor;
the resin extends substantially to the upper edge of the side wall;
the electronic component is a Printed Circuit Board (PCB) or electronic card;
the housing comprises an arched top presenting a filling hole and a vent hole;
the resin is selected from the group consisting of mono- or bi-component epoxy, silicone or polyurethane resins.

The device according to the invention may be, in particular, a housing through which flows intake air for an automotive vehicle, called Temperature and Measurement Air Pressure (TMAP).

The invention also relates to a vehicle equipped with a device according to the invention.

Other features and advantages of the invention will become apparent from reading the description which follows, and upon reviewing the accompanying drawings in which:

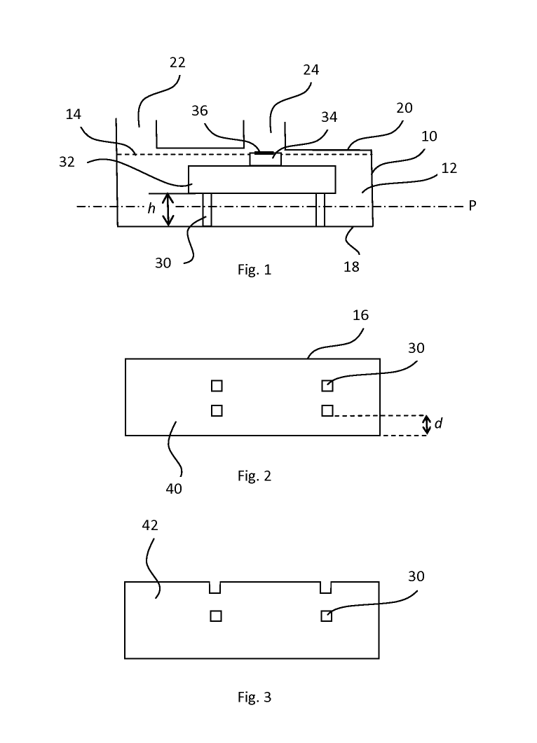

FIG. 1 represents schematically, in median longitudinal section, a device according to the invention;

FIG. 2 represents a section of the device of FIG. 1 according to plane P; and

FIG. 3 represents a variant of the device of FIG. 1, viewed along the plane P.

In the various figures, identical references are used to designate the same or similar bodies.

Unless otherwise indicated, the term “comprising a ” or “including a” means “comprising at least one”.

Unless otherwise indicated, a “resin” is in the solid state.

FIG. 1 represents an exemplary device according to the invention. This device comprises a housing 10 defining a cavity 12 substantially closed, filled with resin 14. The dotted line indicates the upper level of the resin 14. The housing 10 comprises a side wall 16, a bottom 18 and an arched top 20.

The side wall 16 and/or the bottom 18, or even the housing 10, are preferably made of a plastic material, preferably selected from thermoplastics.

The arched top is pierced with a filling hole 22 and a vent hole 24. The pads 30 protrude from the bottom 18.

An electronic component 32, comprising a sensor 34, is placed on the pads 30. The electronic component 32 is submerged in the resin 14, with the exception of a sensing element 36 of the sensor 34 which emerges from the resin 14 so as to be exposed to the environment. The electronic component is well known to one skilled in the art.

The resin is preferably selected from mono- or bi-component epoxy, silicone or polyurethane resins. Preferably, the resin extends substantially up to the arched top.

As shown in FIG. 2, the pads 30 are spaced from the side wall 16 at a distance d greater than 1 mm, the distance d corresponding to the minimum spacing between the pad 30 considered and any point of the side wall 16.

In the embodiment of FIG. 3, some pads 30 are in contact with the side wall.

For manufacturing a device as the one represented in the figures, the electronic component 32 is placed on the pads 30 and the resin in the liquid state is then poured into the cavity 12 via the filling hole 22.

Preferably, before being poured into the housing 10, the liquid resin is degassed, that is to say placed in an environment in which the pressure is reduced, for example at a pressure lower than 20 mbar, for example 10 mbar, in order to extract the gas and, in particular, the air possibly present.

The viscosity of the resin in the liquid state is typically greater than 0.2 Pas and/or lower than 0.5.

As the cavity 12 is progressively filling up, the air which was contained therein escapes through the vent hole 24.

The filling is stopped before the resin covers the sensing element 36. Preferably, the resin submerges the electronic component 32, with the exception of only the sensing element 36, which remains exposed to the environment.

The inventors have found that the spacing of the pads 30 from the side wall 16 releases a passage 40 for the resin which is sufficient to avoid the imprisonment of bubbles.

In the variant of FIG. 3, when a pad is in contact with the side wall 16, no bubbles may occur between the pad and the side wall. In a preferred embodiment, the pad 30 comes into contact with the side wall 16.

The liquid resin is then hardened.

The inventors have found that the absence of bubbles near the pads limits the risk of crack formation likely to contact the electronic component with the outside environment.

The resin can thus ensure protection of the electronic component 32 during a period longer than that of the devices of the prior art, despite the variations in temperature and pressure encountered in an application to a motor vehicle.

It is understood that the invention is not limited to the embodiment described and represented, provided as an illustrative example.

For example, a pad 30 could be placed in a corner 42 of the housing 10.

1. A device comprising:
an electronic component having a sensor provided with a sensing element;
a housing having a side wall and a bottom so as to define a cavity;
a resin filling the cavity so as to submerge the electronic component while letting emerge said sensing element,
the electronic component resting on at least one pad projecting from said side wall or said bottom so as to prevent air bubble formation in the resin, the pad being spaced from the side wall 16 by a distance d greater than 1 mm, or is in contact with said side wall 16.

2. The device according to claim 1, the sensor being a pressure sensor.

3. The device according to claim 1, the resin extending substantially to the upper edge of the side wall.

4. The device according to claim 1, the electronic component being a printed circuit.

5. The device according to claim 1, the housing having an arched top presenting a filling hole and a vent hole.

6. The device according to claim 1, the resin being selected from the group consisting of mono- or bi-component epoxy, silicone or polyurethane resins.

7. The device according to claim 1, in the form of a housing through which flows the intake air for an automotive vehicle.

8. A vehicle equipped with a device according to claim 1.
